(19) United States
(12) Patent Application Publication
(10) Pub. No.: US 2014/0131231 A1
(43) Pub. Date: May 15, 2014

(54) COMPARTMENTALIZED REPAIR KIT FOR ELECTRONIC DEVICES

(71) Applicants: James Walter Linder, Fort Wayne, IN (US); Rachel Grace Linder, Fort Wayne, IN (US); Joshua Richard Patterson, Austin, TX (US)

(72) Inventors: James Walter Linder, Fort Wayne, IN (US); Rachel Grace Linder, Fort Wayne, IN (US); Joshua Richard Patterson, Austin, TX (US)

(21) Appl. No.: 14/076,232

(22) Filed: Nov. 10, 2013

Related U.S. Application Data
(60) Provisional application No. 61/727,077, filed on Nov. 15, 2012.

(51) Int. Cl. H05K 13/00

(52) U.S. Cl. CPC H05K 13/0084
USPC 206/232; 206/725

(57) ABSTRACT

Embodiments disclosed herein are directed towards a compartmentalized housing configured to house components of an electronic device. The compartmentalized housing may include a pictorial parts map disposed on an inner surface of a cover of the compartmentalized housing, the pictorial parts map including an image associated with each type of component of the electronic device. Each image on the pictorial parts map is positioned at a location corresponding to where the type of component should be placed.

### CROSS-REFERENCE TO RELATED APPLICATIONS

This application claims a benefit of priority under 35 U.S.C. §119 to Provisional Application No. 61/727,077, filed on Nov. 15, 2012, entitled “COMPARTMENTALIZED REPAIR KIT FOR ELECTRONIC DEVICES” which is fully incorporated by reference in its entirety.

### TECHNICAL FIELD

This disclosure relates generally to systems and methods for a compartmentalized repair kit for electronic devices. Specifically, this disclosure relates to a pictorial parts map disposed on an inner surface of the compartmentalized repair kit to organize electronic device components during disassembly, reassembly, repairs, and transportation.

### BACKGROUND

Conventionally, to repair transportable electronic devices, such as mobile phones, specialized technicians are encouraged to develop their own systems and methods to organize components of an electronic device, such as screws and processors, during disassembly, reassembly, repairs, and/or transportation.

One conventional method technicians rely on to repair electronic devices includes spreading the components of an electronic device across a work-bench in the order in which the parts were disassembled or placing the components in individual, independent trays. The individual trays are unmarked and are of equal size so as to hold the varying components of the electronic device. Typically, technicians are required to remember the exact order in which the components were removed from the electronic device to successfully re-assemble and repair the electronic device. When re-assembling the electronic device, smaller components such as screws may get lost, or get left out of the electronic device altogether during re-assembly.

Components that are spread across a work bench can be easily lost, misplaced, or moved. For example, movements in the air generated by a fan or air-conditioning unit may cause disassembled components of the electronic device placed on the work bench to be moved off the bench. If components are unintentionally moved, technicians may not realize that the components have been displaced, may not be able to find the components. Further, if the technician does not have access to each of the components, the technician may have difficulty determining what stage the technician was at.

By placing components in independent trays, if technicians are repairing multiple electronic devices over a period of time, waiting for replacement parts to arrive, work at different locations, or are interrupted for any reason, technicians may not remember which components are placed in what independent trays, which components are associated with what devices, and/or lose track of what stage in the repair process the technician was in.

If components are missing from an electronic device after re-assembly, the electronic device may not work or may work for a period time with the missing screw, but it may cause issues to develop over time. To this end, even experienced technicians struggle to organize disassembled components of an electronic device during repair.

Furthermore, if technicians are interrupted while repairing the electronic device for any reason, such as an interruption by a customer walking into a retail location, the end of the workday, etc., then the technician or another technician will waste time determining what stage of the repair he/she was in. As such, technicians having their own systems and methods for completing repairs for electronic devices make it difficult for different technicians to assist in repairing the same electronic device. Other technicians may not be able to continue the repair without expending a lot of time determining what stage of the repair process the other technician was in.

Accordingly, needs exist for more efficient and effective repair kits for electronic devices.

### SUMMARY

Embodiments described herein relate to systems and methods for a compartmentalized repair kit and organizer for electronic devices, where the compartments for the repair kit are positioned in a meaningful order. In embodiments, the repair kit (referred to hereinafter as “compartmentalized housing”) is configured to house each and every component for an electronic device.

The compartmentalized housing may include compartments, a repair manual, and a pictorial parts map. The pictorial parts map may be associated with various models of electronic devices coupled to an inner surface of the lid of the compartmentalized housing identifying where the different types of components should be placed within the compartmentalized housing.

In a first state, the compartmentalized housing may include empty compartments. As a technician repairs an electronic device, the technician may disassemble the electronic device and place the components in compartments or sections of the compartmentalized housing associated with the type of component. In embodiments, each compartment may be configured to store or secure a specific type component of an electronic device, such that if the electronic device is in a disassembled state, each type of component may be stored in a different compartment. In embodiments, the compartmentalized housing may not include extra compartments for components that are not associated with the electronic device.

The compartments and/or sections may be identified in a pictorial parts map. In embodiments, the pictorial parts map may be positioned on an inner surface of the compartmentalized housing, such that if a lid of the compartmentalized housing is open the inner surface of the compartmentalized housing and the pictorial parts map may face a technician. The compartments of the compartmentalized housing may be organized using unique identifiers comprised of numbers, letters, Roman Numerals, or any combination of an alpha-numerical system to associate components and a component compartment. In further embodiments, the pictorial parts map, layers, compartments, and/or slots of the compartmentalized housing, fields of a work order form, and steps of a manual may be color coordinated, such that a technician may determine what part of the electronic device should be placed in a layer, compartment, and/or slot for a corresponding step in the manual. In embodiments, each compartment and/or section may be identified in the manual in bold, capitalized letters. For example, in one embodiment the following identification system may be used:
The front row may be numbered SLOT 1-14
The larger compartments may lettered COMPARTMENT A-G The open areas may be marked with Roman Numerals ZONE I-V

In embodiments, the pictorial parts map may be disposed on an inner surface of a lid of the compartmentalized housing. The pictorial parts map may include pictorial identifiers corresponding to the location of the compartments where different components should be placed. By having a pictorial parts map, technicians may be able to visually determine where components of the electronic device are supposed to be housed allowing for simpler, faster and/or more efficient repairs. In embodiments, a compartmentalized housing may include a plurality of pictorial parts map, where each of the pictorial parts maps is associated with repairing a different type of electronic device. Therefore, a technician may utilize the different pictorial parts map to repair different types of electronic devices.

In embodiments, the pictorial parts map may be a mapping of the exact layout of the lower surface of the compartmentalized housing, including pictures of components configured to be disposed within the different compartments or sections of the compartmentalized housing. In other embodiments, the pictorial parts map may be a scaled mapping of the layout of the lower surface of the compartmentalized housing.

In embodiments, the compartmentalized housing may include a plastic sleeve on an outer surface of the lid to hold a work order associated with the repair. The work order may allow a technician to record completed steps in the manual and determine what steps in the manual that the technician has completed. Therefore, if the technician loses his place, quits, gets fired, ceases work on a project, etc., another technician can look at the work order to determine the stage of repair associated with the electronic device.

In embodiments, the manual may include steps correlated with what components are placed within their compartment.

In embodiments, the steps may include actions that the technician should complete, a component of the electronic device associated with the action, a pictorial identifier of the component, and a unique identifier of the compartment or section of the compartmentalized housing where the component should be placed. Therefore, if new technician is working on a repair, the new technician can quickly view the repair manual, pictorial parts map, and compartments within the compartmentalized housing to determine which step of the repair a previous technician was on, simply by comparing the parts map and the compartments to see which compartments are filled. In embodiments, a technician may also look at the compartment housing, manual and work order to quickly determine what the last step the technician or another technician completed. In embodiments, fields of the work order form may also be color coordinated, such that the technician may determine the color of the last step recorded in the work order repair form, confirm the corresponding color of the layer, compartment, and/or slot within the compartmentalized housing includes a corresponding piece of the electronic device.

Embodiments described herein may increase the efficiency when technicians repair electronic devices by limiting or reducing the time used to determine how much work has been completed on a repair and/or what stage in the repair the technician is at by using the work order repair form, manual, and the pictorial parts map to compare the parts map to the compartments and determine how much work has been completed by noting in the work order repair form how many compartments are filled. Further, the compartmentalized housing as described herein allows for technicians to complete repairs for electronic devices at a plurality of different locations, which increases their mobility when repairing electronic devices. For example, if a technician goes onsite to a client's office, starts disassembling an electronic device to replace the screen, but realizes the speaker is damaged during the disassembly, the technician can close the compartmentalized housing and take it back to a repair shop so the technician can retrieve a replacement speaker and repair the electronic device there.

These, and other, aspects of the invention will be better appreciated and understood when considered in conjunction with the following description and the accompanying drawings. The following description, while indicating various embodiments of the invention and numerous specific details thereof, is given by way of illustration and not of limitation. Many substitutions, modifications, additions or rearrangements may be made within the scope of the invention, and the invention includes all such substitutions, modifications, additions or rearrangements.

### BRIEF DESCRIPTION OF THE DRAWINGS

The drawings accompanying and forming part of this specification are included to depict certain aspects of the invention. A clearer impression of the invention, and of the components and operation of systems provided with the invention, will become more readily apparent by referring to the exemplary, and therefore nonlimiting, embodiments illustrated in the drawings, wherein identical reference numerals designate the same components. Note that the features illustrated in the drawings are not necessarily drawn to scale.

FIG. 1 depicts one embodiment of a compartmentalized housing configured to house components of an electronic device.

FIG. 2 depicts one embodiment of a bottom portion of a compartmentalized housing.

FIG. 3 depicts one embodiment of a pictorial parts map.

FIG. 4 depicts one embodiment of the top of a closed lid a lid of a compartmentalized housing.

FIG. 5 depicts one embodiment of a compartmentalized housing configured to store components of an electronic device.

FIG. 6 depicts one embodiment of a compartmentalized housing configured to store components of an electronic device.

FIG. 7 depicts one embodiment of an instruction manual including corresponding identifiers for the placement of components of an electronic device within a compartmentalized housing.

### DETAILED DESCRIPTION

The invention and the various features and advantageous details thereof are explained more fully with reference to the nonlimiting embodiments that are illustrated in the accompanying drawings and detailed in the following description.

Descriptions of well-known starting materials, processing techniques, components and equipment are omitted so as not to unnecessarily obscure the invention in detail.

It should be understood, however, that the detailed description and the specific examples, while indicating preferred embodiments of the invention, are given by way of illustration only and not by way of limitation. Various substitutions, modifications, additions and/or rearrangements within the spirit and/or scope of the underlying inventive concept will become apparent to those skilled in the art from this disclosure.

As used herein, the terms “comprises,” “comprising,” “includes,” “including,” “has,” “having” or any other variation thereof, are intended to cover a non-exclusive inclusion. For example, a process, article, or apparatus that comprises a list of elements is not necessarily limited to only those elements but may include other elements not expressly listed or inherent to such process, article, or apparatus.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, any examples or illustrations given herein are not to be regarded in any way as restrictions on, limits to, or express definitions of, any term or terms with which they are utilized. Instead, these examples or illustrations are to be regarded as being described with respect to one particular embodiment and as illustrative only. Those of ordinary skill in the art will appreciate that any term or terms with which these examples or illustrations are utilized will encompass other embodiments which may or may not be given therewith or elsewhere in the specification and all such embodiments are intended to be included within the scope of that term or terms. Language designating such nonlimiting examples and illustrations includes, but is not limited to: “for example,” “for instance,” “e.g.,” “in one embodiment.”

Embodiments disclosed herein are directed towards a compartmentalized housing that reduces errors, and increases efficiency and organization while repairing an electronic device. Embodiments include a pictorial parts map on an inner surface of the compartmentalized housing. The pictorial parts map identifies a location where the components and/or type of component should be placed within the compartmentalized housing. Therefore, technicians are less likely to lose tiny screws and other components that comprise the electronic device, even if the compartmentalized housing is not paired with an instruction manual. Also, embodiments reduce the space used for repairing an electronic device by having a centralized, compartmentalized housing that includes compartments for each component and/or type of component associated with an electronic device.

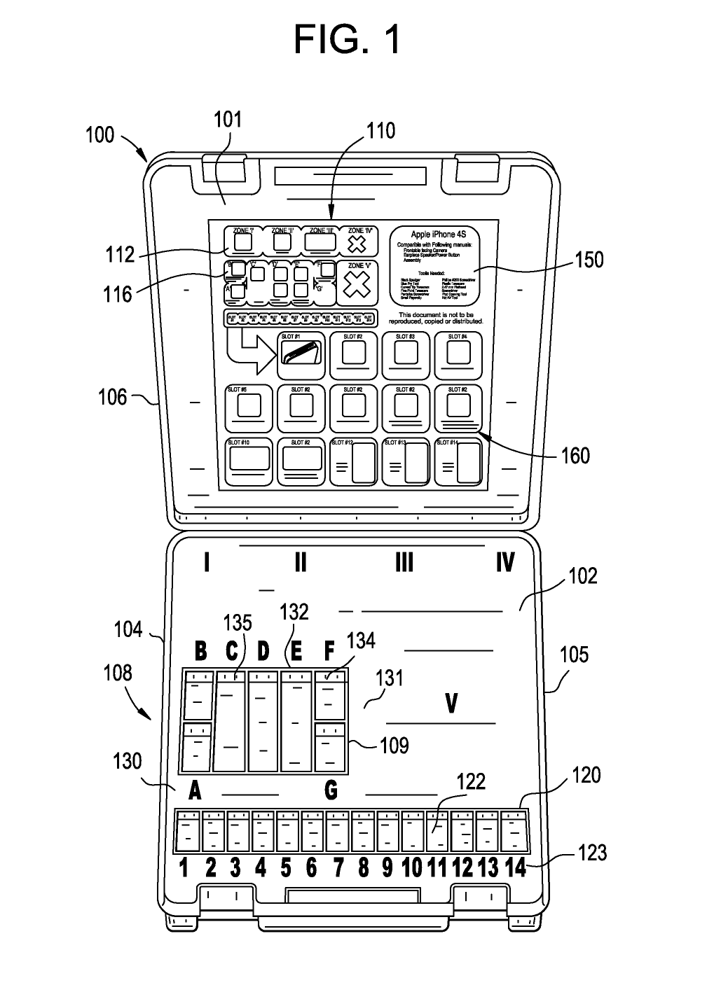

FIG. 1 depicts one embodiment of a compartmentalized housing 100 configured to house components of an electronic device, such as a cell phone, tablet computer, camera, or any other mobile electronic device during repair, assembly, disassembly, and/or harvesting parts.

Compartmentalized housing 100 may have compartments, partitions or sections configured to house each unique component and/or type of component of the electronic device. Compartmentalized housing 100 may include an upper portion 106 and a lower portion 108 configured to open, close, and be sealed together via any known coupling mechanism. Compartmentalized housing 100 may include a specific compartment for each component or type of component for the electronic device. In one embodiment, compartmentalized housing 100 may only include compartments that are associated with a specific component or type of component of the electronic device. By having compartments to house a specific component or type of components of the electronic device, technicians may more efficiently and effectively repair the electronic device. However, one skilled in the art will appreciate that in other embodiments, compartmentalized housing 100 may have additional compartments to house extra components which may or may not be associated with an electronic device. Compartmentalized housing 100 may be comprised of a plastic material, which in one embodiment may be 1/16″ inches thick. The plastic material may be a translucent, clear and/or partially translucent material in various colors. In one embodiment, the colors of the compartmentalized housing 100 may be associated with a particular model and/or type of an electronic device. Further, compartmentalized housing 100 may be 14⅝″ in length, 13⅞″ in width, and 2″ in height.

Upper portion 106 may include a contoured handle (not shown) to make compartmentalized housing 100 easier to transport. Upper portion 106 of compartmentalized housing 100 may also include pictorial parts map 110.

Pictorial parts map 110 may be a pictorial parts map disposed on an inner surface of a lid 101 of compartmentalized housing 100. Pictorial parts map 110 may include a device repair identifier 150, which describes what electronic device compartmentalized housing 100 is configured to be repaired utilizing compartmentalized housing 100, what manual should be used with compartmentalized housing 100, and what tools are desired to perform the repair for the associated device.

Pictorial parts map 110 may include a picture 112 associated with each component and/or type of component for an electronic device and a compartment identifier 116 identifying which compartment in the partitioned housing 130 a component should be placed in during repair. Pictorial parts map 110 may also include an enlarged component section 160. Enlarged component section 160 may be configured to illustrate pictures of components and the unique identifier that the component should be placed in.

Pictorial parts map 110 may be coupled on an inner surface of lid 101 such that pictorial parts map will not become separated from compartmentalized housing, and so that while a technician is repairing an electronic device the technician can quickly determine where to place the components of the electronic device.

In one embodiment, pictorial parts map 110 may have substantially the same layout or the same layout as the compartments 130 within partitioned housing 100. Pictorial parts map 110 may be drawn to be the same size as partitioned housing 130 and/or be a scaled version of partitioned housing 130. By pictorial parts map 110 illustrating pictures corresponding to the components of the electronic device, technicians may easily visually recognize the location within partitioned housing 130 where they should place each of the components of an electronic device. One skilled in the art will appreciate that instead of having pictorial parts map 110 disposed on an inner surface of lid 101 of compartmentalized housing 100, pictorial parts map 110 may be disposed on an inner surface of compartmentalized housing 110 below the partitioned housing 130.

Lower portion 108 of compartmentalized housing 110 may include partitioned housing 130. Partitioned housing 130 may be disposed on lower portion 108 of compartmentalized housing 100 that is opposite pictorial map 110. Partitioned housing 130 may include an antistatic material layer 102, first compartment 120, and second compartment 131.

Antistatic material layer 102 may be a layer of antistatic material, such as an anti-static mat roll or anti-static foam. As used hereinafter the term antistatic material may refer to an anti-static mat roll or an anti-static form individually or collectively. In embodiments, antistatic material layer 102 may be comprised of materials that create an anti-static effect. The antistatic effect caused by antistatic material may prevent or limit localized electronic charges from being deposited onto the components of the electronic device disposed on antistatic material layer 102. Antistatic material layer 102 may be a substantially flat surface configured to hold larger components of an electronic device, such as a logic boards, battery covers, mid-frames, displays, digitizers, or any other component for an electronic device. Antistatic material layer 102 may have a height such that if compartmentalized housing 100 is in a closed position, lid 101 will apply compressive force to the components to hold components placed on antistatic material layer 102 in place. Antistatic material layer 102 may be 9 1/16″ in length, 13¼″ in width, and ¼″ in height, the second antistatic material layer may be 14″ in length, 13″ in width and ½″ in height. Compartmentalized housing 100 may include a second antistatic material layer (not shown) that corresponds in shape to antistatic material layer 102, such that the second antistatic material layer may be overlaid and cover a top of antistatic material layer 102, while compartments 131 and 120 are covered by the second antistatic material layer. If compartmentalized housing 100 is in a closed position, lid 101 may apply compressive force to the second antistatic material layer to hold components of the electronic device in place. In one embodiment, the second antistatic material layer may be substantially the same shape as partitioned housing 130, such that the second antistatic material layer may be overlaid and cover the entire partitioned housing 130 including compartments 120 and 131

A first portion of antistatic material layer 102 may extend from a first side 104 of partitioned housing 130 to a second side 105 of partitioned housing 130. A second portion of antistatic material layer 102 may extend from a first side 109 of first compartment 120 to a second side 105 of partitioned housing 130.

First compartment 120 may be positioned near to or adjacent to a side wall 140 of partitioned housing 130. The area between side wall 140 and the first compartment 120 may be filled with a layer of antistatic matter. First compartment 120 may include slots 122 that are fixed to partitioned housing 130 or are removable from partitioned housing 130. In one embodiment, first compartment 120 may include a plurality of slots 122 that are configured to hold smaller parts of an electronic device, such as screws. Specific slot 122 and the unique identifier 123 for each slot 122. In one embodiment, each slot 122 may be 1¼″ in length, 1″ in width, and 1¼″ in height, and have a convex inner surface with a sloped front side for easy removal of a component disposed within slot 122. Each slot 122 may include a unique identifier 123 disposed on a lower surface of slot 122 or between slot 122 and sidewall 140. The unique identifier 123 may be an alphabetical, chamber/letter, number, or alphanumerical identifier. Furthermore, pictorial parts map 110 may include a graphical representation for each slot 122 including a picture of a component or associated with a component that should be placed within a Slots 122 may be positioned such that the components that are configured to be removed first from the electronic device are positioned on the left side of slots 122, while the components that are configured to be later, as determined by the corresponding steps in an instruction manual, removed are positioned on the right side of slots 122. Accordingly, the positioning of the components associated with slots 122 are positioned in a meaningful order.

Second compartment 131 may be positioned substantially in the middle of partitioned housing 130 close to or adjacent to first side 104. Second compartment 131 may be positioned above first compartment 120, closer to a hinge of compartment housing. The area between first side and second compartment 131, and first compartment 120 and second compartment 130 may be filled with a layer of antistatic matter. Therefore, first compartment 120 and second compartment 131 may be held in place and secured when disposed within partitioned housing 130. Second compartment 131 may include slots 132 that are fixed to partitioned housing 130 or are removable from partitioned housing 130. In one embodiment, second compartment 131 may include a plurality of slots 132 that are configured to hold components of an electronic device, such as speakers, EMI shields, batteries charging ports, cameras etc. Each slot 132 may include a unique identifier 133, which may be an alphabetical, character, number, or alphanumerical identifier. In one embodiment, second compartment 131 may have seven slots, with three larger slots 135 and four smaller slots 134. In one embodiment, larger slots 135 may be 1¼″ in length, 4″ in width, and 1¼″ in height, and smaller slots 134 may be 1¼″ in length, 2 9/16″ in width and 1¼″ in height.

Pictorial parts map 110 may include a graphical representation for each slot 132 including a picture of a component or associated with a component that should be placed within a specific slot 132 and the unique identifier 133 for each slot 132. Slots 132 may be positioned such that the components that are configured to be removed first from the electronic device are positioned on the upper side of slots 132, while the components that are configured to be later removed, as determined by the corresponding steps in an instruction manual, are positioned on the lower side of slots 132. Accordingly, the positioning of the components associated with slots 132 are positioned in a meaningful order.

In one embodiment, antistatic layer 102, slots 122, and slots 132 may be labeled with numbers, letters, roman numerals, or any other unique identifier as illustrated on pictorial parts map 110 for easy, visual identification of where the components are or should be placed.

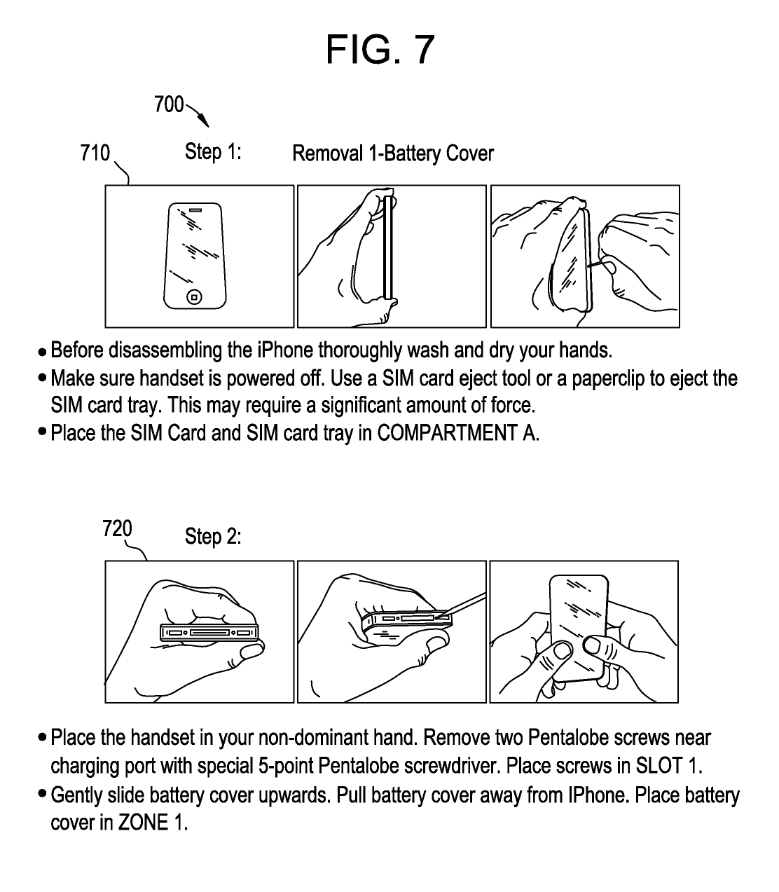

Furthermore, compartmentalized housing 100 may include a manual (as shown in FIG. 7). The manual may include steps or stage associated with repairing, disassembling or reassembling an electronic device. Each step or stage within the manual may include a reference to the unique identifier associated with the placement of the component within compartmentalized housing 100 and a picture of the component that should be placed within a respective slot. In embodiments, each step within the manual may also include a unique color identifier that corresponds to a layer, compartment, and/or slot within compartmentalized housing 100. Additionally, the pictorial parts map may also be color coordinated, and each compartment, layer, and/or slot depicted within the pictorial parts map may be colored differently. Therefore, each step in the manual may be color coordinated to correspond with a field in the work order repair form, layer, compartment, and/or slot within compartmentalized housing 100, and associated location depicted on pictorial parts map 110.

Utilizing the picture of the component in the manual and the unique identifier of the slot in the manual to match the picture of the component on pictorial parts map 110, the placement of the component on pictorial parts maps 110, and the unique identifier of the component on the pictorial parts 110, a technician may be able to determine the corresponding placement of the component within lower portion 108 of compartmentalized housing 110.

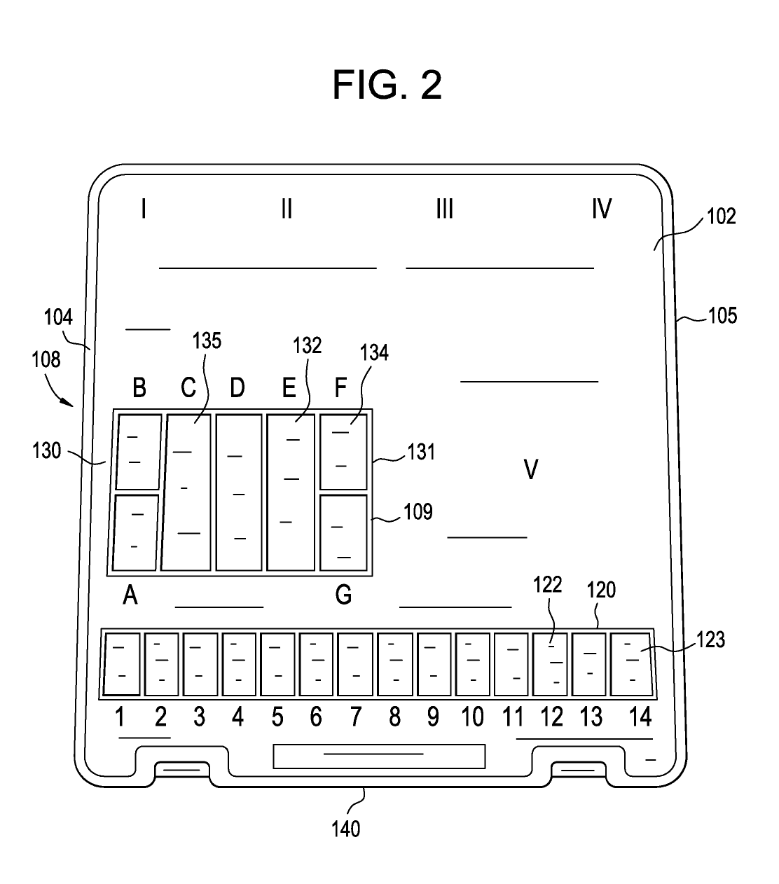

FIG. 2 depicts one embodiment of partitioned housing 130. In one embodiment, partitioned housing 130 may be 13″ in width, 13″ in length and 2⅖″ in height.

As stated above, partitioned housing 130 may include an antistatic layer 102, first compartment 120, and second compartment 131. Positioned on a bottom surface of compartmentalized housing 100 may be an identification layer, which in one embodiment may be ¼″ thick, have a 13″ width, and have a 13″ length. On a top surface of the identification layer the unique identifier for each slot associated with a component of the electronic device may be inscribed, illustrated and/or shown at a position corresponding to the location of the slot in partitioned housing 130. In another embodiment, a picture of a component and/or the unique identifier associated with each slot may be inscribed, illustrated and/or shown on a top surface of identification layer. One skilled in the art will appreciate that instead of having an identification layer, the unique identifier for each slot may be instead positioned at the bottom of the slots or in front of the slots.

Disposed adjacent to identification layer may be an antistatic material layer 102. Antistatic material layer 102 may have orifices corresponding to first compartment 120 and second compartment 131. Therefore, first and second compartments 120 and 131 may be secured in place in partitioned housing 130 via the antistatic material layer 102. In one embodiment, antistatic material layer may be ¾″ in height, have a 13″ width, and have a 13″ length.

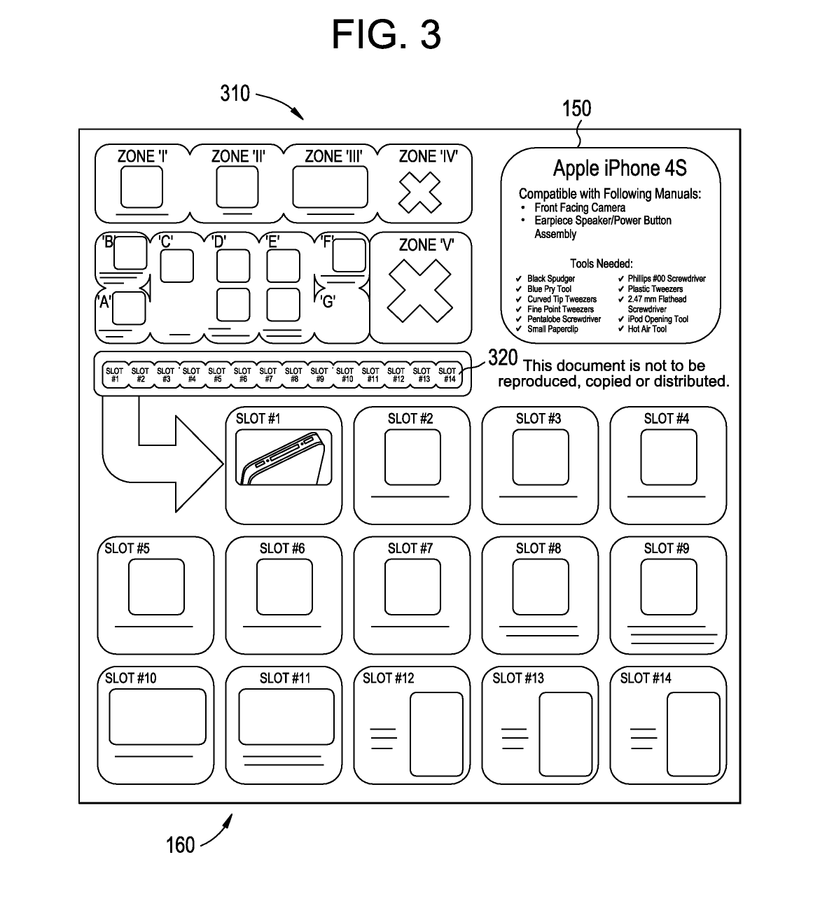

FIG. 3 depicts a pictorial parts map 110. Pictorial parts map 310 may include picture/visual illustrations corresponding to each component that has a respective slot or compartment within compartmentalized housing. The picture/visual illustration may be a picture of the component and or component type. Furthermore, the picture illustration corresponding to each component may be positioned in a respective location similar to the location of the slot for the component.

Therefore, by looking at the pictorial parts map 110 a technician can easily and efficiently determine which components should be placed in slot of a compartmentalized housing.

In another embodiment, the pictorial parts map 310 may be placed on an inner surface of the lid of the compartmentalized housing. In one embodiment, pictorial parts map 310 may be configured at a 1-1 scale, equaling the height and width of partitioned housing. In other embodiments, pictorial parts map 110 may not be drawn at a 1-1 scale as the partitioned housing, and instead be scaled at any factor such that the dimensions of the pictorial parts map 110 are scaled dimensions of the partitioned housing. If pictorial parts map 310 is not drawn to scale of the partitioned housing, then pictorial parts map 150 may include larger identifiers 160 corresponding to smaller slots 320 of the partitioned housing. The larger identifiers 160 may allow pictorial parts 110 to be a scaled mapping of the portioned housing, while illustrating the unique identifier for associated with the location of the component within the portioned housing and a picture of the component.

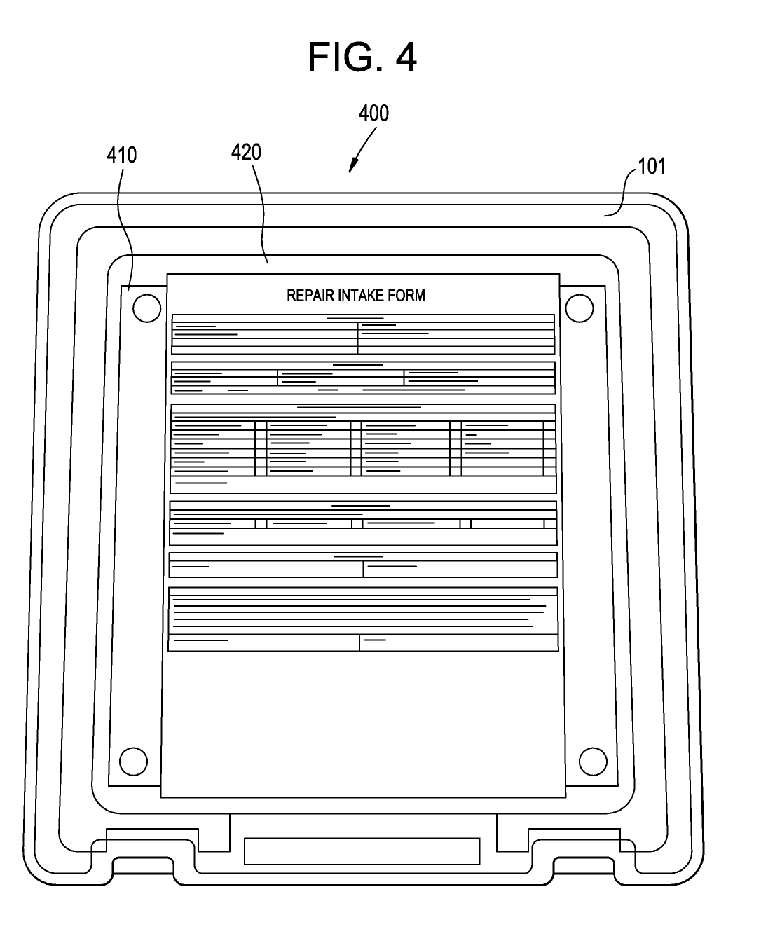

FIG. 4 depicts one embodiment of compartmentalized housing 400, within a cover 420 and a work order form 410.

Compartmentalized housing 400 may include cover 420.

Cover 420 may include a plastic sleeve configured to hold at least one work order form 410 associated with the repair of an electronic device. A technician may use the work order to track or record which stage in the repair process of an electronic device he last completed.

If a technician has to stop repairing the electronic device or another technician is completing the repair, any technician can look at work repair form 410 to determine what type of repair is needed. The technician may then compare a pictorial parts map, components disposed within compartments of a compartmentalized housing, and the associated steps of a repair manual to determine what the next stage in the repair should be. In embodiments, the technician could view the manual and the last step completed on the work order to determine the last step completed of repairing the electronic device. The work order form 410 may state the type of repair desired or required for the electronic device. For instance, the work order form 410 may state that the type of repair needed is associated with the following:
screen
charging port
volume button
speaker
microphone, etc.

A technician may quickly determine the type of repair is desired by looking at the unique identifier and color coordination of the layer, slots, and/or compartments depicted in compartmentalized housing, the parts map, and/or the instruction manual.

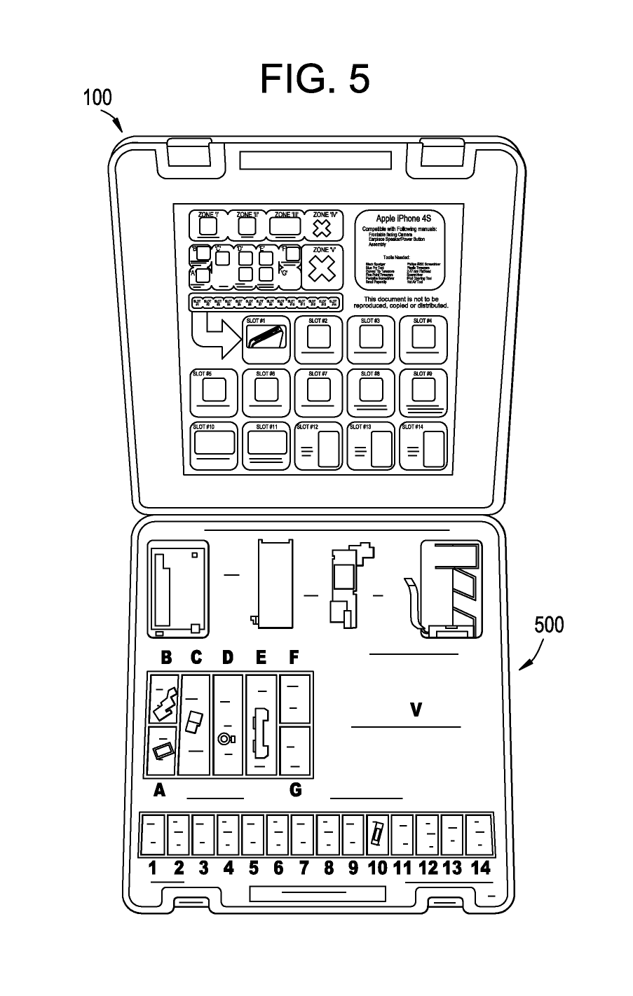

FIG. 5 depicts one embodiment of a compartmentalized housing 100 with components placed within partitioned housing 500. The components may be placed within the different sections of partitioned housing 500 based on the locations of the components on the pictorial parts map. One skilled in the art will appreciate that each component type of an electronic device is placed at a different location on or within partitioned housing 500, where the different components of different parts of the electronic device are housed in different compartments of the partitioned housing 500.

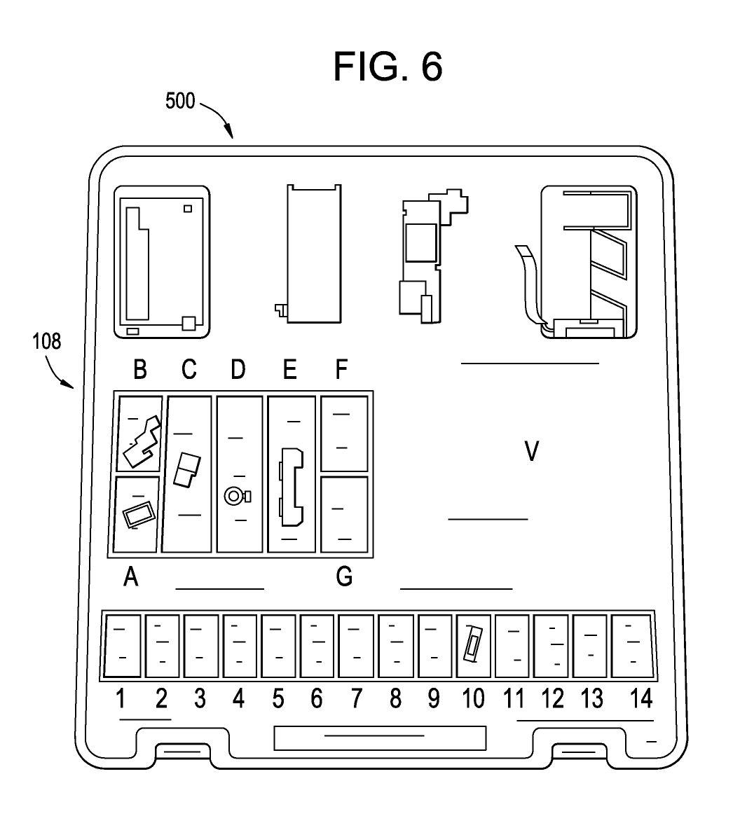

FIG. 6 depicts one embodiment of a detailed view of the lower portion 108 of partitioned housing 500. As depicted in FIG. 6, larger components of an electronic device may be disposed in larger compartments within partitioned housing than the smaller components, which may be disposed in smaller compartments. In embodiments, the layout, sizing and/or shape of the partitioned housing 500 may correspond to the different types of components within an electronic device.

FIG. 7 depicts one embodiment of a repair manual 700 corresponding to a compartmentalized housing for a specific electronic device. Repair manual 700 may correspond to a specific electronic device, a type of electronic device (i.e. a smart phone with a front facing camera, tablet, etc.) On the front of repair manual may include a title of the type of repair associated with the repair manual 700. Repair manual 700 may include a series of steps 710, 720 configured to assist a technician repair an electronic device.

Each step 710, 720 may include a pictorial identifier of the component associated with the step and a unique identifier of compartment within a compartmentalized housing where the component should be placed. In embodiments, the pictorial identifier of the component may be the same pictorial identifier of the component within the pictorial parts map, and the unique identifier of the compartment within each step 720 may also be the same unique identifier of the component within the pictorial parts map.

Therefore, while repairing an electronic device a technician may quickly view the pictorial identifier of the component within a step 710, 720 of repair manual 700, match the pictorial identifier within the step 710, 720 with the pictorial identifier within the pictorial parts map, and determine the compartment associated with the unique identifier determining the placement of the component within the compartmentalized housing.

In the foregoing specification, embodiments have been described with reference to specific embodiments. However, one of ordinary skill in the art appreciates that various modifications and changes can be made without departing from the scope of the invention. Accordingly, the specification and figures are to be regarded in an illustrative rather than a restrictive sense, and all such modifications are intended to be included within the scope of invention.

Although the invention has been described with respect to specific embodiments thereof, these embodiments are merely illustrative, and not restrictive of the invention. The description herein of illustrated embodiments of the invention is not intended to be exhaustive or to limit the invention to the precise forms disclosed herein (and in particular, the inclusion of any particular embodiment, feature or function is not intended to limit the scope of the invention to such embodiment, feature or function).

Rather, the description is intended to describe illustrative embodiments, features and functions in order to provide a person of ordinary skill in the art context to understand the invention without limiting the invention to any particularly described embodiment, feature or function. While specific embodiments of, and examples for, the invention are described herein for illustrative purposes only, various equivalent modifications are possible within the spirit and scope of the invention, as those skilled in the relevant art will recognize and appreciate.

As indicated, these modifications may be made to the invention in light of the foregoing description of illustrated embodiments of the invention and are to be included within the spirit and scope of the invention. Thus, while the invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the invention.

Reference throughout this specification to “one embodiment,” “an embodiment,” or “a specific embodiment” or similar terminology means that a particular feature, structure, or characteristic described in connection with the embodiment is included in at least one embodiment and may not necessarily be present in all embodiments. Thus, respective appearances of the phrases “in one embodiment,” “in an embodiment,” or “in a specific embodiment” or similar terminology in various places throughout this specification are not necessarily referring to the same embodiment.

Furthermore, the particular features, structures, or characteristics of any particular embodiment may be combined in any suitable manner with one or more other embodiments. It is to be understood that other variations and modifications of the embodiments described and illustrated herein are possible in light of the teachings herein and are to be considered as part of the spirit and scope of the invention.

In the description herein, numerous specific details are provided, such as examples of components and/or methods, to provide a thorough understanding of embodiments of the invention. One skilled in the relevant art will recognize, however, that an embodiment may be able to be practiced without one or more of the specific details, or with other apparatus, systems, assemblies, methods, components, materials, parts, and/or the like. In other instances, well-known structures, components, systems, materials, or operations are not specifically shown or described in detail to avoid obscuring aspects of embodiments of the invention. While the invention may be illustrated by using a particular embodiment, this is not and does not limit the invention to any particular embodiment and a person of ordinary skill in the art will recognize that additional embodiments are readily understandable and are a part of this invention.

It will also be appreciated that one or more of the elements depicted in the drawings/figures can also be implemented in a more separated or integrated manner, or even removed or rendered as inoperable in certain cases, as is useful in accordance with a particular application. Additionally, any signal arrows in the drawings/figures should be considered only as exemplary, and not limiting, unless otherwise specifically noted.

Furthermore, the term “or” as used herein is generally intended to mean “and/or” unless otherwise indicated. As used herein, a term preceded by “a” or “an” (and “the” when antecedent basis is “a” or “an”) includes both singular and plural of such term (i.e., that the reference “a” or “an” clearly indicates only the singular or only the plural). Also, as used in the description herein, the meaning of “in” includes “in” and “on” unless the context clearly dictates otherwise.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component.

What is claimed is:

1. A compartmentalized housing, comprising:
a partitioned housing including a plurality of compartments configured to house components of an electronic device, wherein each compartment is configured to house a different component of the electronic device;
a pictorial parts map disposed on an inner surface of a cover of the compartmentalized housing, the pictorial parts map including images associated with the components of the electronic device, wherein each of the images is positioned at a location corresponding to where the type of component should be placed within the partitioned housing.

2. The compartmentalized housing of claim 1, wherein the plurality of compartments are different sized to correspond to the different sizes of the components of the electronic device.

3. The compartmentalized housing of claim 1, wherein the pictorial parts map is a mapping of the partitioned housing.

4. The compartmentalized housing of claim 1, wherein the plurality of compartments include a plurality of slots, and each of the plurality of slots include a unique identifier based on the positioned of the plurality of slots within the partitioned housing.

5. The compartmentalized housing of claim 4, wherein the pictorial parts map include the unique identifier associated with each of the plurality of slots, and the unique identifier on the pictorial parts map associated with each of the plurality of slots is positioned at a location corresponding to the location of the respective slot.

6. The compartmentalized housing of claim 5, wherein the pictorial parts map includes a scaled mapping of the partitioned housing.

7. The compartmentalized housing of claim 6, wherein the pictorial parts map includes a first section and a second section, the first section including the unique identifier associated with the plurality of slots, and the second section including the unique identifier associated with the plurality of slots and a pictorial identifier of the component configured to be disposed with each of the plurality of slots.

8. The compartmentalized housing of claim 4, further comprising:
a repair manual including a plurality of steps to repair the electronic device, each of the plurality of steps corresponding to a different one of the plurality of components of the electronic device, and each of the plurality of steps including a pictorial identifier and the unique identifier corresponding to one of the plurality of components.

9. The compartmentalized housing of claim 1, further comprising:
an antistatic material disposed on a surface of the partitioned housing, the antistatic material being configured to create an anti-static effect to limit localized electronic charges from being deposited onto components of the electronic device disposed on the material.

10. The compartmentalized housing of claim 1, wherein none of the plurality of components are configured to house components that are not associated with the electronic device.

11. A method for repairing an electronic device with a compartmentalized housing, the method comprising:
storing a plurality of components of an electronic device in a plurality of compartments within a partitioned housing, the plurality of compartments being positioned within the compartmentalized housing, wherein the placement of the stored plurality of components within the partitioned housing is based on a pictorial parts map disposed on an inner surface of a cover of the compartmentalized housing, the pictorial parts map including images associated with the components of the electronic device, wherein each of the images is positioned at a location corresponding to where the type of component should be placed within the partitioned housing.

12. The method of claim 11, wherein the plurality of compartments are different sized to correspond to the different sizes of the components of the electronic device.

13. The method of claim 11, wherein the pictorial parts map is a mapping of the partitioned housing.

14. The method of claim 11, wherein the plurality of compartments include a plurality of slots, and each of the plurality of slots include a unique identifier based on the positioned of the plurality of slots within the partitioned housing.

15. The method of claim 14, wherein the pictorial parts map include the unique identifier associated with each of the plurality of slots, and the unique identifier on the pictorial parts map associated with each of the plurality of slots is positioned at a location corresponding to the location of the respective slot.

16. The method of claim 15, wherein the pictorial parts map includes a scaled mapping of the partitioned housing.

17. The method of claim 16, wherein the pictorial parts map includes a first section and a second section, the first section including the unique identifier associated with the plurality of slots, and the second section including the unique identifier associated with the plurality of slots and a pictorial identifier of the component configured to be disposed with each of the plurality of slots.

18. The method of claim 14, further comprising:
reviewing a repair manual including a plurality of steps to repair the electronic device, each of the plurality of steps corresponding to a different one of the plurality of components of the electronic device, and each of the plurality of steps including a pictorial identifier and the unique identifier corresponding to one of the plurality of components.

19. The method of claim 11, further comprising:
positioning an antistatic material on a surface of the partitioned housing;
generating, by the antistatic material, an anti-static effect to limit localized electronic charges from being deposited onto components of the electronic device disposed on the antistatic material.

20. The method of claim 11, wherein none of the plurality of components are configured to house components that are not associated with the electronic device.
